(19) United States
(12) Patent Application Publication
(10) Pub. No.: US 2026/0095153 A1
(43) Pub. Date: Apr. 2, 2026

(54) DIFFERENTIAL PHASE SHIFTER

(71) Applicant: ELECTRONICS AND TELECOMMUNICATIONS RESEARCH INSTITUTE, Daejeon (KR)

(72) Inventors: Seonjeong PARK, Daejeon (KR); Kyung Hwan PARK, Daejeon (KR); Ja Yol LEE, Daejeon (KR)

(21) Appl. No.: 19/337,334

(22) Filed: Sep. 23, 2025

(30) Foreign Application Priority Data
Oct. 2, 2024 (KR) 10-2024-0133937
Aug. 20, 2025 (KR) 10-2025-0115474

(51) Int. Cl. H03H 11/16; H03M 1/66

(52) U.S. Cl. CPC H03H 11/16; H03M 1/66

(57) ABSTRACT

A phase shifter includes an I/Q generator that generates an in-phase signal and a quadrature-phase signal based on an input signal, a vector synthesis circuit that generates a first differential signal pair and a second differential signal pair based on the in-phase signal and the quadrature-phase signal, and generates an output signal based on the first differential signal pair and the second differential signal pair, a first digital-to-analog converter (DAC) that transmits first and second current control signals to the vector synthesis circuit to control the in-phase signal, and a second DAC that transmits third and fourth current control signals to the vector synthesis circuit to control the quadrature-phase signal. The vector synthesis circuit includes a first common-source amplifier, a second common-source amplifier, a third common-source amplifier, and a fourth common-source amplifier.

### CROSS-REFERENCE TO RELATED APPLICATIONS

This application claims priority under 35 U.S.C. § 119 to Korean Patent Application No. 10-2024-0133937 filed on Oct. 2, 2024, and Korean Patent Application No. 10-2025-0115474 filed on Aug. 20, 2025, in the Korean Intellectual Property Office, the disclosures of which are incorporated by reference herein in their entireties.

### BACKGROUND

### 1. Field of the Invention

The present disclosure relates to a differential phase shifter, and more specifically, to a differential phase shifter that generates differential signal pairs within a vector synthesis circuit without an additional balun and synthesizes an in-phase signal and a quadrature-phase signal based on the differential signal pairs.

### 2. Description of Related Art

In a phased-array antenna system, a direction of a beam is controlled by adjusting a gain or a phase of a signal applied to each antenna element. A phase shifter connected to each antenna element adjusts a phase of a transmit/receive signal and enable beam steering in a specific direction.

Recently, a phase shifter has been proposed that generates a differential signal using a balun placed at a input stage and generates an output vector based on it. In this case, when a passive balun is used to generate the differential signal, a loss occurs, and when an active balun is used to generate the differential signal, power consumption increases. In addition, as the phase changes, an input impedance of a vector synthesis circuit changes, causing errors in I/Q signals, which in turn leads to phase and gain errors in an output vector.

Meanwhile, in the case of a phase shifter using gm slicing, which generates a desired vector by weighting gm cells of a vector synthesis circuit, baluns with a relatively large area are integrated to generate the differential signal. When active baluns are used to reduce loss, a design area and power consumption increase. Furthermore, as the number of transistors turned on within the vector synthesis circuit differs depending on the phase change, an input impedance of the vector synthesis circuit changes, which in turn leads to phase and gain errors in an output vector. In addition, the gm slicing structure has a limitation in increasing the resolution, and due to an asymmetrical layout between the sliced gm cells, the phase error occurs at high frequencies.

Therefore, there is a need for a phase shifter that reduces power consumption and area of a balun and has a constant input impedance even with phase changes.

### SUMMARY

An object of the present disclosure is to provide a differential phase shifter that generates differential signal pairs within a vector synthesis circuit without an additional balun and synthesizes an in-phase signal and a quadrature-phase signal based on the differential signal pairs.

A phase shifter according to an embodiment of the present disclosure includes an I/Q generator that generates an in-phase signal and a quadrature-phase signal based on an input signal, a vector synthesis circuit that generates a first differential signal pair and a second differential signal pair based on the in-phase signal and the quadrature-phase signal, and generates an output signal based on the first differential signal pair and the second differential signal pair, a first digital-to-analog converter (DAC) that transmits first and second current control signals to the vector synthesis circuit to control the in-phase signal; and a second DAC that transmits third and fourth current control signals to the vector synthesis circuit to control the quadrature-phase signal. The vector synthesis circuit includes a first common-source amplifier, a second common-source amplifier, a third common-source amplifier, and a fourth common-source amplifier.

In an embodiment, the vector synthesis circuit includes first to fourth transistors. The first common-source amplifier includes the first transistor. The second common-source amplifier includes the second transistor. The third common-source amplifier includes the third transistor. The fourth common-source amplifier includes the fourth transistor. A drain terminal of the first transistor and a gate terminal of the second transistor are electrically connected. A drain terminal of the third transistor and a gate terminal of the fourth transistor are electrically connected.

In an embodiment, the first transistor generates a first phase signal based on the in-phase signal. The second transistor generates a second phase signal based on the first phase signal. The first differential signal pair includes the first phase signal and the second phase signal.

In an embodiment, the third transistor generates a third phase signal based on the quadrature-phase signal. The fourth transistor generates a fourth phase signal based on the third phase signal. The second differential signal pair includes the third phase signal and the fourth phase signal.

In an embodiment, the vector synthesis circuit further includes fifth to twelfth transistors. The drain terminal of the first transistor is connected to source terminals of the fifth transistor and the sixth transistor. The drain terminal of the second transistor is connected to source terminals of the seventh transistor and the eighth transistor. The drain terminal of the third transistor is connected to source terminals of the ninth transistor and the tenth transistor. The drain terminal of the fourth transistor is connected to source terminals of the eleventh transistor and the twelfth transistor.

In an embodiment, the fifth transistor and the sixth transistor amplify the first phase signal. The seventh transistor and the eighth transistor amplify the second phase signal. The ninth transistor and the tenth transistor amplify the third phase signal. The eleventh transistor and the twelfth transistor amplify the fourth phase signal.

In an embodiment, the amplified signals from the fifth transistor, the seventh transistor, the ninth transistor, and the eleventh transistor are synthesized to generate a first output phase signal. The amplified signals from the sixth transistor, the eighth transistor, the tenth transistor, and the twelfth transistor are synthesized to generate a second output phase signal. The vector synthesis circuit includes an output balun that generates the output signal based on the first output phase signal and the second output phase signal.

In an embodiment, a first current flows through the fifth transistor and the eighth transistor. A second current flows through the sixth transistor and the seventh transistor. A third current flows through the ninth transistor and the twelfth transistor. A fourth current flows through the tenth transistor and the eleventh transistor. A sum of the first current and the second current is equal to a sum of the third current and the fourth current.

In an embodiment, the first DAC includes a thirteenth transistor and a fourteenth transistor. A gate terminal of the thirteenth transistor is connected to gate terminals of the fifth transistor and the eighth transistor. A gate terminal of the fourteenth transistor is connected to gate terminals of the sixth transistor and the seventh transistor.

In an embodiment, the first current is controlled based on a first control current flowing through the thirteenth transistor. The second current is controlled based on a second control current flowing through the fourteenth transistor.

In an embodiment, the first DAC includes first to eighth binary-weighted current cells. Each of the first to eighth binary-weighted current cells includes a first switch and a second switch that operate complementarily based on a digital code. The first control current is associated with the first switch, and the second control current is associated with the second switch.

In an embodiment, the second DAC includes a fifteenth transistor and a sixteenth transistor. A gate terminal of the fifteenth transistor is connected to gate terminals of the ninth transistor and the twelfth transistor. A gate terminal of the sixteenth transistor is connected to gate terminals of the tenth transistor and the eleventh transistor.

In an embodiment, the third current is controlled based on a third control current flowing through the fifteenth transistor. The fourth current is controlled based on a fourth control current flowing through the sixteenth transistor.

In an embodiment, the second DAC includes ninth to sixteenth binary-weighted current cells. Each of the ninth to sixteenth binary-weighted current cells includes a third switch and a fourth switch that operate complementarily based on the digital code. The third control current is associated with the third switch, and the fourth control current is associated with the fourth switch.

A phase shifter according to an embodiment of the present disclosure includes an I/Q generator that generates an in-phase signal and a quadrature-phase signal based on an input signal, a vector synthesis circuit that generates a first differential signal pair and a second differential signal pair based on the in-phase signal and the quadrature-phase signal, and generates an output signal based on the first differential signal pair and the second differential signal pair, a first digital-to-analog converter (DAC) that transmits first and second current control signals to the vector synthesis circuit to control the in-phase signal, and a second DAC that transmits third and fourth current control signals to the vector synthesis circuit to control the quadrature-phase signal. The vector synthesis circuit includes a first common-gate amplifier, a second common-gate amplifier, a first common-source amplifier, and a second common-source amplifier.

In an embodiment, the vector synthesis circuit includes first to fourth transistors. The first common-gate amplifier includes the first transistor. The second common-gate amplifier includes a third transistor. The first common-source amplifier includes the second transistor. The second common-source amplifier includes the fourth transistor. A source terminal of the first transistor and a gate terminal of the second transistor are electrically connected. A source terminal of the third transistor and a gate terminal of the fourth transistor are electrically connected.

In an embodiment, the first transistor generates a first phase signal based on the in-phase signal. The second transistor generates a second phase signal based on the first phase signal. The first differential signal pair includes the first phase signal and the second phase signal. The third transistor generates a third phase signal based on the quadrature-phase signal. The fourth transistor generates a fourth phase signal based on the third phase signal. The second differential signal pair includes the third phase signal and the fourth phase signal.

In an embodiment, the vector synthesis circuit further includes fifth to twelfth transistors. A drain terminal of the first transistor is connected to source terminals of the fifth transistor and the sixth transistor. A drain terminal of the second transistor is connected to source terminals of the seventh transistor and the eighth transistor. A drain terminal of the third transistor is connected to source terminals of the ninth transistor and the tenth transistor. A drain terminal of the fourth transistor is connected to source terminals of the eleventh transistor and the twelfth transistor.

In an embodiment, the fifth transistor and the sixth transistor amplify the first phase signal. The seventh transistor and the eighth transistor amplify the second phase signal. The ninth transistor and the tenth transistor amplify the third phase signal. The eleventh transistor and the twelfth transistor amplify the fourth phase signal. The amplified signals from the fifth transistor, the seventh transistor, the ninth transistor, and the eleventh transistor are synthesized to generate a first output phase signal. The amplified signals from the sixth transistor, the eighth transistor, the tenth transistor, and the twelfth transistor are synthesized to generate a second output phase signal. The vector synthesis circuit includes an output balun that generates the output signal based on the first output phase signal and the second output phase signal.

A phase shifter according to an embodiment of the present disclosure includes an I/Q generator that generates an in-phase signal and a quadrature-phase signal based on an input signal, a vector synthesis circuit that generates a first differential signal pair and a second differential signal pair, and generates an output signal based on the first differential signal pair and the second differential signal pair, a first digital-to-analog converter (DAC) that transmits first and second current control signals to the vector synthesis circuit to control the in-phase signal, and a second DAC that transmits third and fourth current control signals to the vector synthesis circuit to control the quadrature-phase signal. The vector synthesis circuit includes a first differential signal pair generator that generates the first differential signal pair based on the in-phase signal, and a second differential signal pair generator that generates the second differential signal pair based on the quadrature-phase signal.

### BRIEF DESCRIPTION OF THE DRAWINGS

The above and other aspects and features of embodiments of the present disclosure will become apparent by describing in detail non-limiting example embodiments thereof with reference to the accompanying drawings.

FIG. 1 illustrates an example of a differential phase shifter according to an embodiment of the present disclosure.

FIG. 2 illustrates an example of an I/Q generator according to an embodiment of the present disclosure.

FIG. 3 illustrates an example of a vector synthesis circuit according to an embodiment of the present disclosure.

FIG. 4 illustrates an example of digital-to-analog converters according to an embodiment of the present disclosure.

FIG. 5 illustrates an operation of a differential phase shifter according to an embodiment of the present disclosure.

FIG. 6 illustrates another example of a vector synthesis circuit according to an embodiment of the present disclosure.

FIG. 7 illustrates another example of a vector synthesis circuit according to an embodiment of the present disclosure.

### DETAILED DESCRIPTION

Hereinafter, embodiments of the present disclosure may be described in detail and clearly to such an extent that an ordinary one in the art easily implements the present disclosure.

Hereinafter, the preferred embodiments of the present disclosure will be described in detail with reference to the accompanying drawings. The advantages, features, and methods of achieving the present invention will become more apparent from the following detailed description taken in conjunction with the accompanying drawings. However, it should be understood that the present invention is not limited to the embodiments described herein and may be embodied in various other forms. Rather, the embodiments introduced here are provided to make the disclosed content thorough and complete, and to ensure that the concepts of the disclosure are sufficiently conveyed to those skilled in the art, and the disclosure is defined only by the scope of the claims. Throughout the specification, the same reference numerals refer to the same components.

The terms used in the specification are for the purpose of describing the embodiments and are not intended to limit the disclosure. In this specification, the singular form includes the plural form unless specifically stated otherwise in the context. The terms ‘comprise’ and/or ‘comprising’ used in the specification do not exclude the presence or addition of one or more other components, actions, and/or elements. Furthermore, since it is based on preferred embodiments, the reference numerals presented in the description are not necessarily limited by the order of presentation.

The embodiments described in this specification will be explained with reference to ideal examples such as cross-sectional and/or plan views of the disclosure. In the drawings, the thickness of the layers and regions may be exaggerated for the effective explanation of the technical content. Therefore, the shape of the example may be altered due to manufacturing techniques and/or tolerances. Thus, the embodiments of the present disclosure are not limited to the specific forms illustrated, but include changes in the shape created according to the manufacturing process.

Components that are described in the detailed description with reference to the terms “unit”, “module”, “block”, “˜er or ˜or”, etc. and function blocks illustrated in drawings will be implemented with software, hardware, or a combination thereof. For example, the software may be a machine code, firmware, an embedded code, and application software. For example, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

In the present disclosure, each of the phrases such as “A or B,” “at least one of A and B,” “at least one of A or B,” “A, B, or C,” “at least one of A, B, and C,” and “at least one of A, B, or C” is intended to encompass any one of the listed elements and all possible combinations thereof.

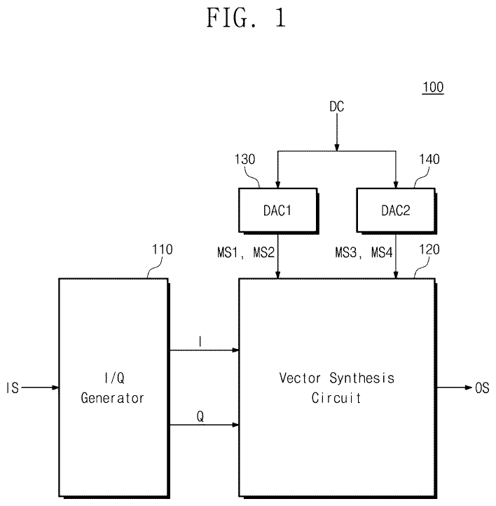

FIG. 1 illustrates an example of a differential phase shifter according to an embodiment of the present disclosure. Referring to FIG. 1, a differential phase shifter 100 may include an I/Q generator 110, a vector synthesis circuit 120, a first digital-to-analog converter (DAC) 130, and a second DAC 140.

The I/Q generator 110 may generate an in-phase signal I having an in-phase component and a quadrature-phase signal Q having a quadrature-phase component based on an input signal IS. The in-phase signal I may have a phase difference of 90 degrees from the quadrature-phase signal Q.

The vector synthesis circuit 120 may generate an output signal OS based on the in-phase signal I and the quadrature-phase signal Q. For example, the vector synthesis circuit 120 may generate a first differential signal pair based on the in-phase signal I. The vector synthesis circuit 120 may generate a second differential signal pair based on the quadrature-phase signal Q. The vector synthesis circuit 120 may generate a third differential signal pair based on the first differential signal pair and the second differential signal pair. The vector synthesis circuit 120 may generate the output signal OS based on the third differential signal pair.

The first DAC 130 may generate first and second current control signals MS1, MS2 based on a digital code DC. The first DAC 130 may control the in-phase signal I based on the first and second current control signals MS1, MS2.

The second DAC 140 may generate third and fourth current control signals MS3, MS4 based on the digital code DC. The second DAC 140 may control the quadrature-phase signal Q based on the third and fourth current control signals MS3, MS4.

In FIG. 1, the vector synthesis circuit 120 may perform an operation to generate the first differential signal pair and the second differential signal pair. That is, the differential phase shifter 100 integrates a function of a balun, which occupies a large area and consumes significant power, into the vector synthesis circuit 120, thereby reducing an area and power consumption caused by the balun.

In addition, in the differential phase shifter 100, since an input impedance of the vector synthesis circuit 120 does not change even if a phase and a gain are adjusted, errors of signals output from the I/Q generator 110 (e.g., the in-phase signal I and the quadrature-phase signal Q) may be low.

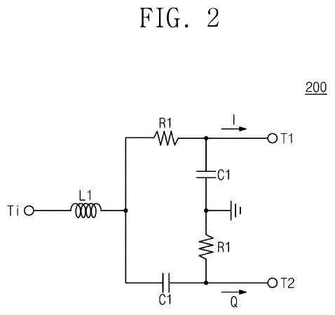

FIG. 2 illustrates an example of an I/Q generator according to an embodiment of the present disclosure. Referring to FIG. 1 and FIG. 2, an I/Q generator 200 may include a first inductor L1, first resistors R1, and first capacitors C1. The I/Q generator 200 may receive an input signal IS through an input terminal T1 and generate an in-phase signal I and a quadrature-phase signal Q based on the received input signal IS. The in-phase signal I and the quadrature-phase signal Q may be transmitted to the vector synthesis circuit 120 through a first terminal T1 and a second terminal T2, respectively.

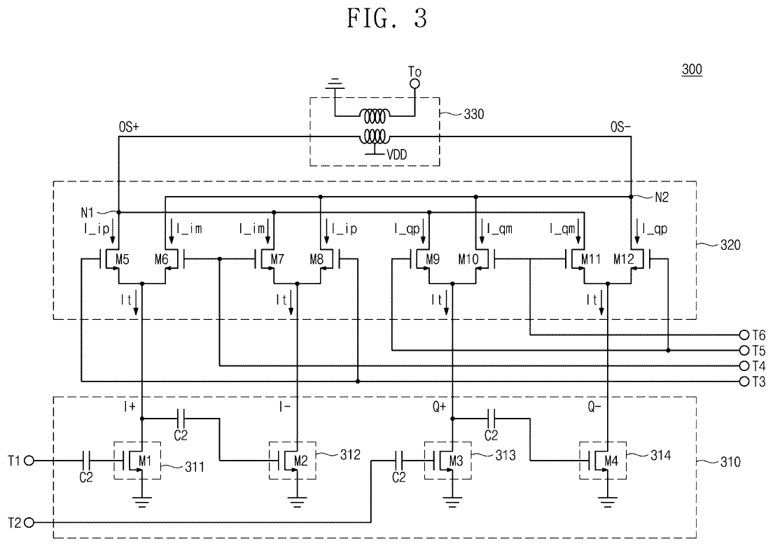

FIG. 3 illustrates an example of a vector synthesis circuit according to an embodiment of the present disclosure. Referring to FIG. 1 and FIG. 3, a vector synthesis circuit 300 may include a differential signal generation unit 310, a vector synthesis unit 320, and an output balun 330.

The differential signal generation unit 310 may include a first common-source amplifier 311, a second common-source amplifier 312, a third common-source amplifier 313, and a fourth common-source amplifier 314. The first common-source amplifier 311 may include a first transistor M1. The second common-source amplifier 312 may include a second transistor M2. The third common-source amplifier 313 may include a third transistor M3. The fourth common-source amplifier 314 may include a fourth transistor M4. The first to fourth transistors M1-M4 may each be an NMOS transistor. Each of the first common-source amplifier 311, the second common-source amplifier 312, the third common-source amplifier 313, and the fourth common-source amplifier 314 may output a signal by utilizing the characteristic that a phase difference between input and output signals of a common-source amplifier is 180 degrees.

In the differential signal generation unit 310, a second capacitor C2 may be connected between a first terminal T1 and a gate terminal of the first transistor M1, between a drain terminal of the first transistor M1 and a gate terminal of the second transistor M2, between a second terminal T2 and a gate terminal of the third transistor M3, and between a drain terminal of the third transistor M3 and a gate terminal of the fourth transistor M4. The drain terminal of the first transistor M1 and the gate terminal of the second transistor M2 are electrically connected, and the drain terminal of the third transistor M3 and the gate terminal of the fourth transistor M4 may be electrically connected.

The differential signal generation unit 310 may generate a first differential signal pair based on an in-phase signal I. For example, the in-phase signal I may be applied to the gate terminal of the first transistor M1 through the first terminal T1. A first phase signal I+, which is an amplified in-phase signal I, may be formed at the drain terminal of the first transistor M1. That is, the first transistor M1 may amplify the in-phase signal I to generate the first phase signal I+. A second phase signal I− having a phase difference of 180 degrees from the first phase signal I+ may be formed at a drain terminal of the second transistor M2. The second transistor M2 may invert a phase of the first phase signal I+ by 180 degrees to generate the second phase signal I−. That is, the second transistor M2 may generate the second phase signal I− by utilizing the characteristic that a phase difference between input and output signals of a common-source amplifier is 180 degrees. The first differential signal pair may include the first phase signal I+ and the second phase signal I− (Or the first phase signal I+ and the second phase signal I− may constitute the first differential signal pair). The differential signal generation unit 310 may output the first differential signal pair to the vector synthesis unit 320.

The differential signal generation unit 310 may generate a second differential signal pair based on a quadrature-phase signal Q. For example, the quadrature-phase signal Q may be applied to the gate terminal of the third transistor M3 through the second terminal T2. A third phase signal Q+, which is an amplified quadrature-phase signal Q, may be formed at the drain terminal of the third transistor M3. That is, the third transistor M3 may amplify the quadrature-phase signal Q to generate the third phase signal Q+. A fourth phase signal Q− vhaving a phase difference of 180 degrees from the third phase signal Q+ may be formed at a drain terminal of the fourth transistor M4. The fourth transistor M4 may invert a phase of the third phase signal Q+ by 180 degrees to generate the fourth phase signal Q−. That is, the fourth transistor M4 may generate the fourth phase signal Q− by utilizing the characteristic that a phase difference between input and output signals of a common-source amplifier is 180 degrees. The second differential signal pair may include the third phase signal Q+ and the fourth phase signal Q− (Or the third phase signal Q+ and the fourth phase signal Q− may constitute the second differential signal pair). The differential signal generation unit 310 may output the second differential signal pair to the vector synthesis unit 320.

The vector synthesis unit 320 may include fifth to twelfth transistors M5-M12. The fifth to twelfth transistors M5-M12 may each be an NMOS transistor.

A drain terminal of the fifth transistor M5, a drain terminal of the seventh transistor M7, a drain terminal of the ninth transistor M9, and a drain terminal of the eleventh transistor M11 may be connected to each other. A drain terminal of the sixth transistor M6, a drain terminal of the eighth transistor M8, a drain terminal of the tenth transistor M10, and a drain terminal of the twelfth transistor M12 may be connected to each other.

A source terminal of the fifth transistor M5, a source terminal of the sixth transistor M6, and the drain terminal of the first transistor M1 may be connected to each other. A source terminal of the seventh transistor M7, a source terminal of the eighth transistor M8, and the drain terminal of the second transistor M2 may be connected to each other. A source terminal of the ninth transistor M9, a source terminal of the tenth transistor M10, and the drain terminal of the third transistor M3 may be connected to each other. A source terminal of the eleventh transistor M11, a source terminal of the twelfth transistor M12, and the drain terminal of the fourth transistor M4 may be connected to each other.

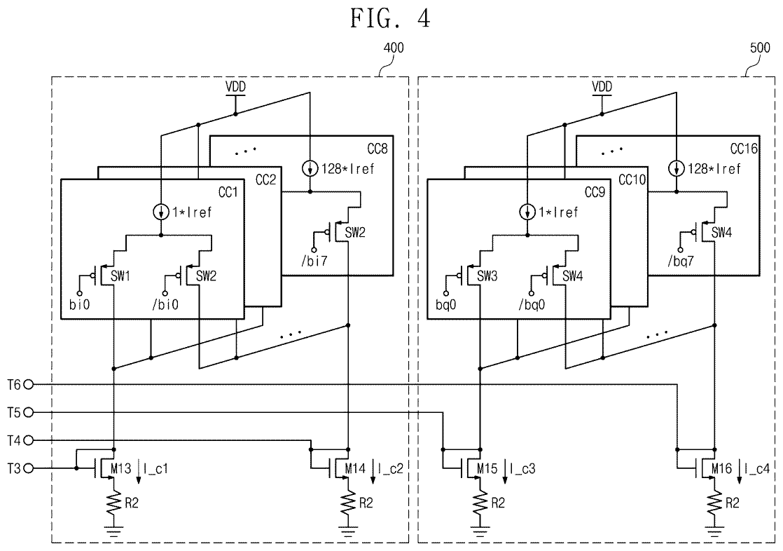

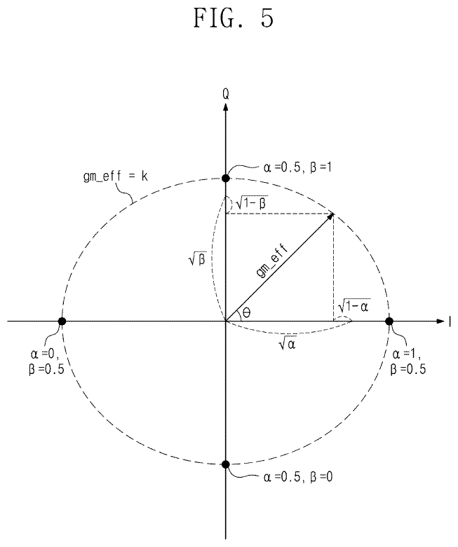

The magnitude of currents flowing through the fifth transistor M5 and the eighth transistor M8 may be the same, the magnitude of currents flowing through the sixth transistor M6 and the seventh transistor M7 may be the same, the magnitude of currents flowing through the ninth transistor M9 and the twelfth transistor M12 may be the same, and the magnitude of currents flowing through the tenth transistor M10 and the eleventh transistor M11 may be the same. For example, a first current I_ip may flow through the fifth transistor M5 and the eighth transistor M8, a second current I_im may flow through the sixth transistor M6 and the seventh transistor M7, a third current I_qp may flow through the ninth transistor M9 and the twelfth transistor M12, and a fourth current I_qm may flow through the tenth transistor M10 and the eleventh transistor M11. An explanation of ratios of the first to fourth currents I_ip, I_im, I_qp, I_qm will be described below with reference to FIG. 4 and FIG. 5.

The magnitude of currents flowing through the first to fourth transistors M1-M4 may be the same. For example, a fifth current It may flow through the first to fourth transistors M1-M4. Since the fifth current It flows through the first and third transistors M1, M3 regardless of a phase, an input impedance of the vector synthesis circuit 300 (i.e., a load impedance seen at an output terminal of an I/Q generator 110 of FIG. 1) may always be constant. Therefore, gain or phase errors due to a loading effect of the I/Q generator 110 may be reduced.

The vector synthesis unit 320 may generate a third differential signal pair based on the first to fourth phase signals I+, I−, Q+, Q−. That is, the vector synthesis unit 320 may generate the third differential signal pair based on the first differential signal pair and the second differential signal pair.

For example, the first to fourth phase signals I+, I−, Q+, Q− may be applied to the fifth to twelfth transistors. For example, the first phase signal I+ may be applied to the source terminals of the fifth transistor M5 and the sixth transistor M6, the second phase signal I− may be applied to the source terminals of the seventh transistor M7 and the eighth transistor M8, the third phase signal Q+ may be applied to the source terminals of the ninth transistor M9 and the tenth transistor M10, and the fourth phase signal Q− may be applied to the source terminals of the eleventh transistor M11 and the twelfth transistor M12.

The first to fourth phase signals I+, I−, Q+, Q− applied to the fifth to twelfth transistors M5-M12 may be amplified based on transconductances of the fifth to twelfth transistors M5-M12. For example, the first phase signal I+ applied to the fifth transistor M5 may be amplified in proportion to the transconductance of the fifth transistor M5. The first phase signal I+ applied to the sixth transistor M6 may be amplified in proportion to the transconductance of the sixth transistor M6. The second phase signal I-applied to the seventh transistor M7 may be amplified in proportion to the transconductance of the seventh transistor M7. The second phase signal I-applied to the eighth transistor M8 may be amplified in proportion to the transconductance of the eighth transistor M8. The third phase signal Q+ applied to the ninth transistor M9 may be amplified in proportion to the transconductance of the ninth transistor M9. The third phase signal Q+ applied to the tenth transistor M10 may be amplified in proportion to the transconductance of the tenth transistor M10. The fourth phase signal Q− applied to the eleventh transistor M11 may be amplified in proportion to the transconductance of the eleventh transistor M11. The fourth phase signal Q− applied to the twelfth transistor M12 may be amplified in proportion to the transconductance of the twelfth transistor M12.

The amplified signals from the fifth transistor M5, the seventh transistor M7, the ninth transistor M9, and the eleventh transistor M11 are synthesized to generate a first output phase signal OS+ at a first node N1. The amplified signals from the sixth transistor M6, the eighth transistor M8, the tenth transistor M10, and the twelfth transistor M12 are synthesized to generate a second output phase signal OS− at a second node N2. The third differential signal pair may include the first output phase signal OS+ and the second output phase signal OS− (Or the first output phase signal OS+ and the second output phase signal OS− may constitute the third differential signal pair). The second output phase signal OS− may have a phase difference of 180 degrees from the first output phase signal OS+. In an embodiment, the first node N1 may correspond to the (+) node of the output balun 330, and the second node N2 may correspond to the (−) node of the output balun 330.

In an embodiment, the fifth and eighth transistors M5, M8 may each provide a positive transconductance, and the sixth and seventh transistors M6, M7 may each provide a negative transconductance. Therefore, the magnitude of the in-phase signal I may be determined based on the fifth to eighth transistors M5-M8.

In an embodiment, the ninth and twelfth transistors M9, M12 may each provide a positive transconductance, and the tenth and eleventh transistors M10, M11 may each provide a negative transconductance. Therefore, the magnitude of the quadrature-phase signal Q may be determined based on the ninth to twelfth transistors M9-M12.

The output balun 330 may generate an output signal OS based on the third differential signal pair. For example, the output balun 330 may generate the output signal OS based on the first output phase signal OS+ and the second output phase signal OS−. The output balun 330 may output the output signal OS through an output terminal To.

FIG. 4 illustrates an example of digital-to-analog converters according to an embodiment of the present disclosure. Referring to FIG. 1, FIG. 3, and FIG. 4, a first DAC 400 may include a plurality of binary-weighted current cells CC1-CC8, a thirteenth transistor M13, and a fourteenth transistor M14. The thirteenth and fourteenth transistors M13, M14 may each be an NMOS transistor.

Each of the plurality of binary-weighted current cells CC1-CC8 may include a current source, a first switch SW1, and a second switch SW2. The first and second switches SW1, SW2 may each be a PMOS transistor. In each of the plurality of binary-weighted current cells CC1-CC8, a first terminal of the current source is connected to a power supply voltage VDD, and a second terminal of the current source may be connected to a first terminal (e.g., a source terminal) of the first switch SW1 and a first terminal (e.g., a source terminal) of the second switch SW2. In each of the plurality of binary-weighted current cells CC1-CC8, a second terminal (e.g., a drain terminal) of the first switch SW1 is connected to a drain terminal of the thirteenth transistor M13, and a second terminal (e.g., a drain terminal) of the second switch SW2 may be connected to a drain terminal of the fourteenth transistor M14.

In each of the plurality of binary-weighted current cells CC1-CC8, the magnitude of current provided by the current source may be set in a binary-weighted manner based on a reference current Iref. For example, the magnitude of the current provided by the current source of the binary-weighted current cell CC1 may be ‘1*Iref’, the magnitude of the current provided by the current source of the binary-weighted current cell CC2 may be ‘2*Iref’, the magnitude of the current provided by the current source of the binary-weighted current cell CC3 may be ‘4*Iref’, the magnitude of the current provided by the current source of the binary-weighted current cell CC4 may be ‘8*Iref’, the magnitude of the current provided by the current source of the binary-weighted current cell CC5 may be ‘16*Iref’, the magnitude of the current provided by the current source of the binary-weighted current cell CC6 may be ‘32*Iref’, the magnitude of the current provided by the current source of the binary-weighted current cell CC7 may be ‘64*Iref’, and the magnitude of the current provided by the current source of the binary-weighted current cell CC8 may be ‘128*Iref’.

In each of the plurality of binary-weighted current cells CC1-CC8, the first switch SW1 and the second switch SW2 may be complementarily turned on or off based on a digital code DC. For example, the first switch SW1 is turned on or off by a corresponding bit among first control bits bi0-bi7 included in the digital code DC, and the second switch SW2 may be turned on or off by a corresponding bit among an inverted bits /bi0-/bi7 of the first control bits bi0-bi7. As the first and second switches SW1, SW2 included in each of the plurality of binary-weighted current cells CC1-CC8 are turned on or off, a first control current I_c1 flowing through the thirteenth transistor M13 and a second control current I_c2 flowing through the fourteenth transistor M14 may be controlled. That is, the first control current I_c1 and the second control current I_c2 may be controlled based on the digital code DC.

A gate terminal and the drain terminal of the thirteenth transistor M13 may be electrically connected. A gate terminal and the drain terminal of the fourteenth transistor M14 may be electrically connected. A second resistor R2 may be connected between a source terminal of the thirteenth transistor M13 and a ground voltage, and between a source terminal of the fourteenth transistor M14 and the ground voltage.

The gate terminal of the thirteenth transistor M13 may be connected to a gate terminal of a fifth transistor M5 and a gate terminal of an eighth transistor M8.

The first DAC 400 may transmit a first current control signal MS1 to a vector synthesis circuit 300 based on the first control current I_c1, which is the current flowing through the thirteenth transistor M13. For example, the first control current I_c1 may be mirrored to the fifth transistor M5 and the eighth transistor M8. As a result of mirroring, a first current I_ip may flow through the fifth transistor M5 and the eighth transistor M8. The first current I_ip may be proportional to the first control current I_c1.

The gate terminal of the fourteenth transistor M14 may be connected to a gate terminal of a sixth transistor M6 and a gate terminal of a seventh transistor M7.

The first DAC 400 may transmit a second current control signal MS2 to the vector synthesis circuit 300 based on the second control current I_c2, which is the current flowing through the fourteenth transistor M14. For example, the second control current I_c2 may be mirrored to the sixth transistor M6 and the seventh transistor M7. As a result of mirroring, a second current I_im may flow through the sixth transistor M6 and the seventh transistor M7. The second current I_im may be proportional to the second control current I_c2.

As described above, ratios of the first current I_ip and the second current I_im may be determined based on the digital code DC (e.g., the first control bits bi0-bi7).

The second DAC 500 may include a plurality of binary-weighted current cells CC9-CC16, a fifteenth transistor M15, and a sixteenth transistor M16. The fifteenth and sixteenth transistors M15, M16 may each be an NMOS transistor.

Each of the plurality of binary-weighted current cells CC9-CC16 may include a current source, a third switch SW3, and a fourth switch SW4. The third and fourth switches SW3, SW4 may each be a PMOS transistor. In each of the plurality of binary-weighted current cells CC9-CC16, a first terminal of the current source is connected to the power supply voltage VDD, and a second terminal of the current source may be connected to a first terminal (e.g., a source terminal) of the third switch SW3 and a first terminal (e.g., a source terminal) of the fourth switch SW4. In each of the plurality of binary-weighted current cells CC9-CC16, a second terminal (e.g., a drain terminal) of the third switch SW3 is connected to a drain terminal of the fifteenth transistor M15, and a second terminal (e.g., a drain terminal) of the fourth switch SW4 may be connected to a drain terminal of the sixteenth transistor M16.

In each of the plurality of binary-weighted current cells CC9-CC16, the magnitude of current provided by the current source may be set in a binary-weighted manner based on the reference current Iref. For example, the magnitude of the current provided by the current source of the binary-weighted current cell CC9 may be ‘1*Iref’, the magnitude of the current provided by the current source of the binary-weighted current cell CC10 may be ‘2*Iref’, the magnitude of the current provided by the current source of the binary-weighted current cell CC11 may be ‘4*Iref’, the magnitude of the current provided by the current source of the binary-weighted current cell CC12 may be ‘8*Iref’, the magnitude of the current provided by the current source of the binary-weighted current cell CC13 may be ‘16*Iref’, the magnitude of the current provided by the current source of the binary-weighted current cell CC14 may be ‘32*Iref’, the magnitude of the current provided by the current source of the binary-weighted current cell CC15 may be ‘64*Iref’, and the magnitude of the current provided by the current source of the binary-weighted current cell CC16 may be ‘128*Iref’.

In each of the plurality of binary-weighted current cells CC9-CC16, the third switch SW3 and the fourth switch SW4 may be complementarily turned on or off based on the digital code DC. For example, the third switch SW3 is turned on or off by a corresponding bit among second control bits bq0-bq7 included in the digital code DC, and the fourth switch SW4 may be turned on or off by a corresponding bit among an inverted bits /bq0-/bq7 of the second control bits bq0-bq7. As the third and fourth switches SW3, SW4 included in each of the plurality of binary-weighted current cells CC9-CC16 are turned on or off, a third control current I_c3 flowing through the fifteenth transistor M15 and a fourth control current I_c4 flowing through the sixteenth transistor M16 may be controlled. That is, the third control current I_c3 and the fourth control current I_c4 may be controlled based on the digital code DC.

A gate terminal and the drain terminal of the fifteenth transistor M15 may be electrically connected. A gate terminal and the drain terminal of the sixteenth transistor M16 may be electrically connected. The second resistor R2 may be connected between a source terminal of the fifteenth transistor M15 and the ground voltage, and between a source terminal of the sixteenth transistor M16 and the ground voltage.

The gate terminal of the fifteenth transistor M15 may be connected to a gate terminal of a ninth transistor M9 and a gate terminal of a twelfth transistor M12.

The second DAC 500 may transmit a third current control signal MS3 to the vector synthesis circuit 300 based on the third control current I_c3, which is the current flowing through the fifteenth transistor M15. For example, the third control current I_c3 may be mirrored to the ninth transistor M9 and the twelfth transistor M12. As a result of mirroring, a third current I_qp may flow through the ninth transistor M9 and the twelfth transistor M12. The third current I_qp may be proportional to the third control current I_c3.

The gate terminal of the sixteenth transistor M16 may be connected to a gate terminal of a tenth transistor M10 and a gate terminal of an eleventh transistor M11.

The second DAC 500 may transmit a fourth current control signal MS4 to the vector synthesis circuit 300 based on the fourth control current I_c4, which is the current flowing through the sixteenth transistor M16. For example, the fourth control current I_c4 may be mirrored to the tenth transistor M10 and the eleventh transistor M11. As a result of mirroring, a fourth current I_qm may flow through the tenth transistor M10 and the eleventh transistor M11. The fourth current I_qm may be proportional to the fourth control current I_c4.

As described above, ratios of the third current I_qp and the fourth current I_qm may be determined based on the digital code DC (e.g., the second control bits bq0-bq7).

FIG. 5 illustrates an operation of a differential phase shifter according to an embodiment of the present disclosure. In FIG. 5, the horizontal axis may correspond to an in-phase signal I, and the vertical axis may correspond to a quadrature-phase signal Q.

Referring to FIG. 1, FIG. 3, and FIG. 5, first to fourth currents I_ip, I_im, I_qp, I_qm flowing through fifth to twelfth transistors M5-M12 may be represented by the following Equation 1 to Equation 4.

$$I\_ip = It * α \qquad [ Equation 1 ]$$

$$I\_im = It * ( 1 - α ) \qquad [ Equation 2 ]$$

$$I\_qp = It * β \qquad [ Equation 3 ]$$

$$I\_qm = It * ( 1 - β ) \qquad [ Equation 4 ]$$

In Equation 1 to Equation 4, α may represent a ratio of the first current I_ip to a fifth current It, and β may represent a ratio of the second current I_im to the fifth current It.

A transconductance of the in-phase signal I, which is synthesized at a drain terminal of the fifth transistor M5 (i.e., at a first node N1), may be represented by the following Equation 5.

$${g}_{m , I} = {g}_{m , ip} - {g}_{m , im} = k ( \sqrt{α} - \sqrt{1 - α} ) \qquad [ Equation 5 ]$$

In Equation 5, g_{m,l} represents the transconductance of the in-phase signal I, g_{m,tp} represents a positive transconductance due to the fifth transistor M5, and g_{m,im} represents a negative transconductance due to the seventh transistor M7. In this case, since the width and length of the fifth to twelfth transistors M5-M12 are the same, k may be a constant.

A transconductance of the quadrature-phase signal Q, which is synthesized at a drain terminal of the twelfth transistor M12 (i.e., at a second node N2), may be represented by the following Equation 6.

$${g}_{m , Q} = {g}_{m , qp} - {g}_{m , qm} = k ( \sqrt{β} - \sqrt{1 - β} ) \qquad [ Equation 6 ]$$

In Equation 6, g_{m,Q} represents the transconductance of the quadrature-phase signal Q_{m,qp} represents a positive transconductance due to the twelfth transistor M12, and g_{m,im} represents a negative transconductance due to the tenth transistor M10. In this case, since the width and length of the fifth to twelfth transistors M5-M12 are the same, k may be a constant.

At this point, an effective transconductance gm_eff and phase angle θ of a synthesized vector may be represented by the following Equation 7 and Equation 8.

$$gm\_eff = \sqrt{{g}_{m , I}^{2} + {g}_{m , Q}^{2}} = k \sqrt{{( \sqrt{α} - \sqrt{1 - α} )}^{2} + {( \sqrt{β} - \sqrt{1 - β} )}^{2}} \qquad [ Equation 7 ]$$

$$θ = arctan ( \frac{\sqrt{β} - \sqrt{1 - β}}{\sqrt{α} - \sqrt{1 - α}} ) \qquad [ Equation 8 ]$$

In FIG. 5, the circle shown by the dotted line may represent the case where the effective transconductance gm_eff is k. A vector in the first quadrant may be synthesized when 0.5<α<1 and 0.5<β<1. A vector in the second quadrant may be synthesized when 0<α<0.5 and 0.5<β<1. A vector in the third quadrant may be synthesized when 0<α<0.5 and 0<β<0.5. A vector in the fourth quadrant may be synthesized when 0.5<α<1 and 0<β<0.5. For example, when α=β=1, the effective transconductance gm_eff of the synthesized vector may be \sqrt{2k}, and the phase angle θ may be 45 degrees.

Table 1 below shows an example of current ratios a, B for forming eight vectors at 45-degree intervals among vectors where the effective transconductance gm_eff is k.

TABLE 1

| α | 1 − α | β | 1 − β | θ | gm _eff |
|---|---|---|---|---|---|
| 1 | 0 | 0.5 | 0.5 | 0° | k |
| 0.933 | 0.067 | 0.988 | 0.067 | 46° | k |
| 0.6 | 0.5 | 1 | 0 | 90° | k |
| 0.067 | 0.933 | 0.988 | 0.067 | 185° | k |
| 0 | 1 | 0.5 | 0.5 | 180° | k |
| 0.067 | 0.933 | 0.067 | 0.933 | 225° | k |
| 0.5 | 0.5 | 0 | 1 | 270° | k |
| 0.933 | 0.067 | 0.067 | 0.933 | 315° | k |

As described above, a differential phase shifter 100 may synthesize a vector having a desired gain and phase by adjusting the current ratios a, B.

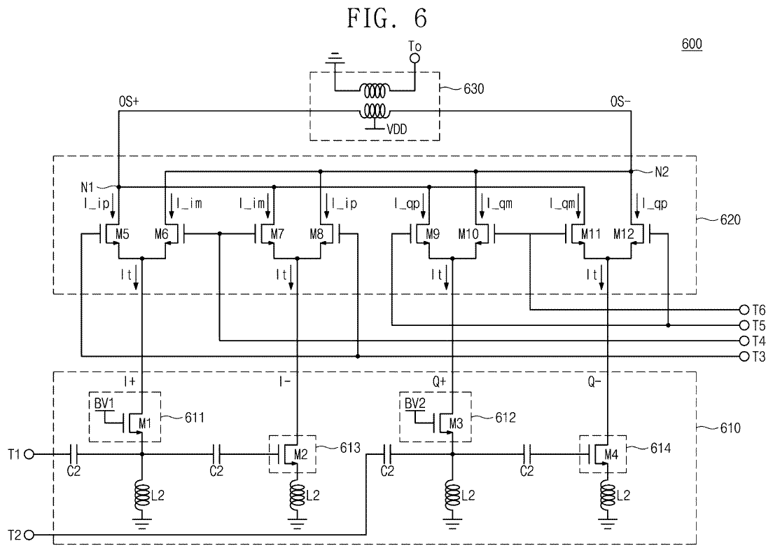

FIG. 6 illustrates another example of a vector synthesis circuit according to an embodiment of the present disclosure. Referring to FIG. 1 and FIG. 6, a vector synthesis circuit 600 may include a differential signal generation unit 610, a vector synthesis unit 620, and an output balun 630.

In FIG. 6, the vector synthesis unit 620 and the output balun 630 may correspond to a vector synthesis unit 320 and an output balun 330 of FIG. 3, respectively. Accordingly, a redundant description is omitted.

The differential signal generation unit 610 may include a first common-gate amplifier 611 and a second common-gate amplifier 612, a first common-source amplifier 613, and a second common-source amplifier 614. The first common-gate amplifier 611 includes a first transistor M1, the second common-gate amplifier 612 includes a third transistor M3, the first common-source amplifier 613 includes a second transistor M2, and the second common-source amplifier 614 includes a fourth transistor M4. The first to fourth transistors M1-M4 may each be an NMOS transistor. Each of the first common-source amplifier 613 and the second common-source amplifier 614 may output a signal by utilizing the characteristic that a phase difference between input and output signals of a common-source amplifier is 180 degrees.

A drain terminal of the first transistor M1 may be connected to a source terminal of a fifth transistor M5 and a source terminal of a sixth transistor M6. A gate terminal of the first transistor M1 may be provided with a first bias voltage BV1.

A drain terminal of the second transistor M2 may be connected to a source terminal of a seventh transistor M7 and a source terminal of an eighth transistor M8.

A drain terminal of the third transistor M3 may be connected to a source terminal of a ninth transistor M9 and a source terminal of a tenth transistor M10. A gate terminal of the third transistor M3 may be provided with a second bias voltage BV2. In an embodiment, the second bias voltage BV2 may be the same as or different from the first bias voltage BV1.

A drain terminal of the fourth transistor M4 may be connected to a source terminal of an eleventh transistor M11 and a source terminal of a twelfth transistor M12.

A second capacitor C2 may be connected between a first terminal T1 and a source terminal of the first transistor M1, between the source terminal of the first transistor M1 and a gate terminal of the second transistor M2, between a second terminal T2 and a source terminal of the third transistor M3, and between the source terminal of the third transistor M3 and a gate terminal of the fourth transistor M4. The source terminal of the first transistor M1 and the gate terminal of the second transistor M2 are electrically connected, and the source terminal of the third transistor M3 and the gate terminal of the fourth transistor M4 may be electrically connected.

A second inductor L2 may be connected between the source terminal of the first transistor M1 and a ground voltage, between a source terminal of the second transistor M2 and the ground voltage, between the source terminal of the third transistor M3 and the ground voltage, and between a source terminal of the fourth transistor M4 and the ground voltage.

The differential signal generation unit 610 may generate a first differential signal pair by utilizing that a phase difference between a signal at the gate terminal of the first common-source amplifier 613 (or a signal at the drain terminal of the first common-gate amplifier 611) and a signal at the drain terminal of the first common-source amplifier 613 is 180 degrees. The differential signal generation unit 610 may generate a second differential signal pair by utilizing that a phase difference between a signal at the gate terminal of the second common-source amplifier 614 (or a signal at the drain terminal of the second common-gate amplifier 612) and a signal at the drain terminal of the second common-source amplifier 614 is 180 degrees.

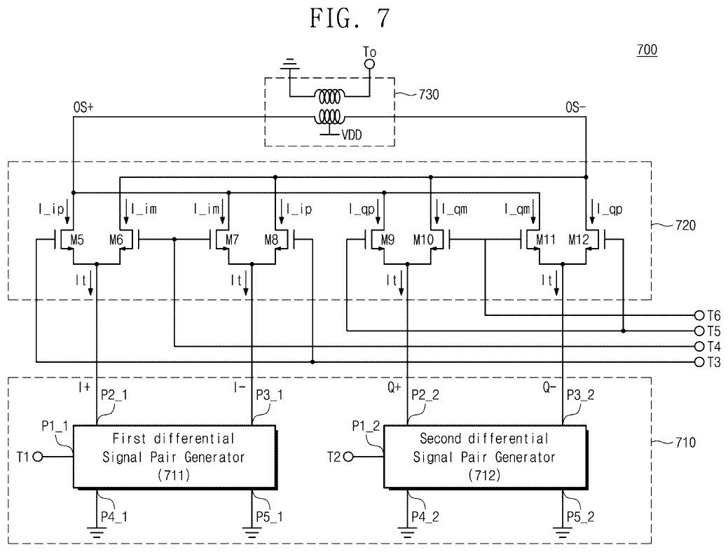

FIG. 7 illustrates another example of a vector synthesis circuit according to an embodiment of the present disclosure. Referring to FIG. 1 and FIG. 7, a vector synthesis circuit 700 may include a differential signal generation unit 710, a vector synthesis unit 720, and an output balun 730.

In FIG. 7, the vector synthesis unit 720 and the output balun 730 may correspond to a vector synthesis unit 320 and an output balun 330 of FIG. 3, respectively. Accordingly, a redundant description is omitted.

The differential signal generation unit 710 may include a first differential signal pair generator 711 and a second differential signal pair generator 712.

The first differential signal pair generator 711 may include first to fifth ports P1_1-P5_1. The first differential signal pair generator 711 may receive an in-phase signal I transmitted from a first terminal T1 through the first port P1_1. The first differential signal pair generator 711 may generate a first differential signal pair based on the in-phase signal I. For example, the first differential signal pair generator 711 may generate a first phase signal I+ and a second phase signal I-based on the in-phase signal I. A phase difference between the first phase signal I+ and the second phase signal I− may be 180 degrees. The first differential signal pair generator 711 may output the first phase signal I+through the second port P2_1 and output the second phase signal I− through the third port P3_1.

The first differential signal pair generator 711 may form a current path for a fifth current It received through the second port P2_1 by being provided with a ground voltage through the fourth port P4_1.

The first differential signal pair generator 711 may form a current path for the fifth current It received through the third port P3_1 by being provided with the ground voltage through the fifth port P5_1.

The second differential signal pair generator 712 may include first to fifth ports P1_2-P5_2. The second differential signal pair generator 712 may receive a quadrature-phase signal Q transmitted from a second terminal T2 through the first port P1_2. The second differential signal pair generator 712 may generate a second differential signal pair based on the quadrature-phase signal Q. For example, the second differential signal pair generator 712 may generate a third phase signal Q+ and a fourth phase signal Q− based on the quadrature-phase signal Q. A phase difference between the third phase signal Q+ and the fourth phase signal Q− may be 180 degrees. The second differential signal pair generator 712 may output the third phase signal Q+ through the second port P2_2 and output the fourth phase signal Q− through the third port P3_2.

The second differential signal pair generator 712 may form a current path for the fifth current It received through the second port P2_2 by being provided with the ground voltage through the fourth port P4_2.

The second differential signal pair generator 712 may form a current path for the fifth current It received through the third port P3_2 by being provided with the ground voltage through the fifth port P5_2.

In the above embodiments, components according to the present disclosure are described by using the terms “first”, “second”, “third”, and the like. However, the terms “first”, “second”, “third”, and the like may be used to distinguish components from each other and do not limit the present disclosure. For example, the terms “first”, “second”, “third”, and the like do not involve an order or a numerical meaning of any form.

The above descriptions are detail embodiments for carrying out the present disclosure. Embodiments in which a design is changed simply or which are easily changed may be included in the present disclosure as well as an embodiment described above. In addition, technologies that are easily changed and implemented by using the above embodiments may be included in the present disclosure.

According to the present disclosure, it is possible to achieve a 20-40% reduction in area and a 25-50% reduction in power compared to conventional phase shifter technologies. In addition, since an input impedance of a vector synthesis circuit is constant regardless of phase and gain adjustment, phase and gain errors of I/Q signals due to load changes of an I/Q generator may be reduced.

1. A phase shifter comprising:
an I/Q generator configured to generate an in-phase signal and a quadrature-phase signal based on an input signal;
a vector synthesis circuit configured to generate a first differential signal pair and a second differential signal pair based on the in-phase signal and the quadrature-phase signal, respectively, and generate an output signal based on the first differential signal pair and the second differential signal pair;
a first digital-to-analog converter (DAC) configured to transmit first and second current control signals to the vector synthesis circuit to control the in-phase signal; and
a second DAC configured to transmit third and fourth current control signals to the vector synthesis circuit to control the quadrature-phase signal,
wherein the vector synthesis circuit includes a first common-source amplifier, a second common-source amplifier, a third common-source amplifier, and a fourth common-source amplifier.

2. The phase shifter of claim 1,
wherein the first common-source amplifier comprises a first transistor configured to generate a first phase signal based on the in-phase signal,
wherein the second common-source amplifier comprises a second transistor configured to generate a second phase signal based on the first phase signal,
wherein the third common-source amplifier comprises a third transistor configured to generate a third phase signal based on the quadrature-phase signal,
wherein the fourth common-source amplifier comprises a fourth transistor configured to generate a fourth phase signal based on the third phase signal.

3. The phase shifter of claim 2, wherein the vector synthesis circuit further includes:
a fifth transistor and a sixth transistor configured to amplify the first phase signal;
a seventh transistor and an eighth transistor configured to amplify the second phase signal;
a ninth transistor and a tenth transistor configured to amplify the third phase signal; and
an eleventh transistor and a twelfth transistor configured to amplify the fourth phase signal.

4. The phase shifter of claim 3,
wherein a first current flows through the fifth transistor and the eighth transistor,
wherein a second current flows through the sixth transistor and the seventh transistor,
wherein a third current flows through the ninth transistor and the twelfth transistor,
wherein a fourth current flows through the tenth transistor and the eleventh transistor, and
wherein a sum of the first current and the second current is equal to a sum of the third current and the fourth current.

5. The phase shifter of claim 4,
wherein the first DAC comprises a thirteenth transistor and a fourteenth transistor,
wherein the second DAC comprises a fifteenth transistor and a sixteenth transistor,
wherein the first current is controlled based on a first control current flowing through the thirteenth transistor,
wherein the second current is controlled based on a second control current flowing through the fourteenth transistor,
wherein the third current is controlled based on a third control current flowing through the fifteenth transistor, and
wherein the fourth current is controlled based on a fourth control current flowing through the sixteenth transistor.

6. The phase shifter of claim 1,
wherein the first DAC comprises first to eighth binary-weighted current cells,
wherein each of the first to eighth binary-weighted current cells comprising a first switch and a second switch that operate complementarily based on a digital code,
wherein the second DAC comprises ninth to sixteenth binary-weighted current cells, and
wherein each of the ninth to sixteenth binary-weighted current cells comprising a third switch and a fourth switch that operate complementarily based on the digital code.

7. The phase shifter of claim 6,
wherein a first control current flowing through the thirteenth transistor included in the first DAC is associated with the first switch,
wherein a second control current flowing through the fourteenth transistor included in the first DAC is associated with the second switch,
wherein a third control current flowing through the fifteenth transistor included in the second DAC is associated with the third switch, and
wherein a fourth control current flowing through the sixteenth transistor included in the second DAC is associated with the fourth switch.

8. The phase shifter of claim 6,
wherein the first switch operates based on first control bits included in the digital code,
wherein the second switch operates based on inverted bits of the first control bits,
wherein the third switch operates based on second control bits included in the digital code, and
wherein the fourth switch operates based on inverted bits of the second control bits.

9. The phase shifter of claim 2,
wherein a drain terminal of the first transistor is electrically connected to a gate terminal of the second transistor, and
wherein a drain terminal of the third transistor is electrically connected to a gate terminal of the fourth transistor.

10. The phase shifter of claim 9,
wherein the vector synthesis circuit further includes:
a fifth transistor and a sixth transistor configured to amplify the first phase signal;
a seventh transistor and an eighth transistor configured to amplify the second phase signal;
a ninth transistor and a tenth transistor configured to amplify the third phase signal; and
an eleventh transistor and a twelfth transistor configured to amplify the fourth phase signal,
wherein a drain terminal of the first transistor is connected to a source terminal of the fifth transistor and a source terminal of the sixth transistor,
a drain terminal of the second transistor is connected to a source terminal of the seventh transistor and a source terminal of the eighth transistor,
a drain terminal of the third transistor is connected to a source terminal of the ninth transistor and a source terminal of the tenth transistor, and
a drain terminal of the fourth transistor is connected to a source terminal of the eleventh transistor and a source terminal of the twelfth transistor.

11. The phase shifter of claim 10,
wherein the first DAC comprises a thirteenth transistor and a fourteenth transistor,
wherein the second DAC comprises a fifteenth transistor and a sixteenth transistor,
wherein a gate terminal of the thirteenth transistor is connected to gate terminals of the fifth transistor and the eighth transistor,
wherein a gate terminal of the fourteenth transistor is connected to gate terminals of the sixth transistor and the seventh transistor,
wherein a gate terminal of the fifteenth transistor is connected to gate terminals of the ninth transistor and the twelfth transistor, and
wherein a gate terminal of the sixteenth transistor is connected to gate terminals of the tenth transistor and the eleventh transistor.

12. The phase shifter of claim 5,
wherein the first DAC is configured to:
transmit the first current control signal based on the first control current; and
transmit the second current control signal based on the second control current, and
wherein the second DAC is configured to:
transmit the third current control signal based on the third control current; and
transmit the fourth current control signal based on the fourth control current.

13. The phase shifter of claim 3,
wherein signals amplified from the fifth transistor, the seventh transistor, the ninth transistor, and the eleventh transistor are combined to generate a first output phase signal,
wherein signals amplified from the sixth transistor, the eighth transistor, the tenth transistor, and the twelfth transistor are combined to generate a second output phase signal, and
wherein the vector synthesis circuit comprises an output balun configured to generate the output signal based on the first output phase signal and the second output phase signal.

14. The phase shifter of claim 2,
wherein the first differential signal pair comprises the first phase signal and the second phase signal, and
wherein the second differential signal pair comprises the third phase signal and the fourth phase signal.

15. A phase shifter comprising:
an I/Q generator configured to generate an in-phase signal and a quadrature-phase signal based on an input signal:
a vector synthesis circuit configured to generate a first differential signal pair and a second differential signal pair based on the in-phase signal and the quadrature-phase signal, respectively, and generate an output signal based on the first differential signal pair and the second differential signal pair:
a first digital-to-analog converter (DAC) configured to transmit first and second current control signals to the vector synthesis circuit to control the in-phase signal; and
a second DAC configured to transmit third and fourth current control signals to the vector synthesis circuit to control the quadrature-phase signal,
wherein the vector synthesis circuit includes a first common-gate amplifier, a second common-gate amplifier, a first common-source amplifier, and a second common-source amplifier.

16. The phase shifter of claim 15,
wherein the first common-gate amplifier comprises a first transistor configured to generate a first phase signal based on the in-phase signal,
wherein the first common-source amplifier comprises a second transistor configured to generate a second phase signal based on the first phase signal,
wherein the second common-gate amplifier comprises a third transistor configured to generate a third phase signal based on the quadrature-phase signal,
wherein the second common-source amplifier comprises a fourth transistor configured to generate a fourth phase signal based on the third phase signal,
wherein the first differential signal pair comprises the first phase signal and the second phase signal, and
wherein the second differential signal pair comprises the third phase signal and the fourth phase signal.

17. The phase shifter of claim 16, wherein the vector synthesis circuit further includes:
a fifth transistor and a sixth transistor configured to amplify the first phase signal;
a seventh transistor and an eighth transistor configured to amplify the second phase signal;
a ninth transistor and a tenth transistor configured to amplify the third phase signal; and
an eleventh transistor and a twelfth transistor configured to amplify the fourth phase signal.

18. The phase shifter of claim 17,
wherein signals amplified from the fifth transistor, the seventh transistor, the ninth transistor, and the eleventh transistor are combined to generate a first output phase signal,
wherein signals amplified from the sixth transistor, the eighth transistor, the tenth transistor, and the twelfth transistor are combined to generate a second output phase signal, and
wherein the vector synthesis circuit comprises an output balun configured to generate the output signal based on the first output phase signal and the second output phase signal.

19. The phase shifter of claim 17,
wherein a source terminal of the first transistor is electrically connected to a gate terminal of the second transistor,
wherein a source terminal of the third transistor is electrically connected to a gate terminal of the fourth transistor,
wherein a drain terminal of the first transistor is connected to a source terminal of the fifth transistor and a source terminal of the sixth transistor,
wherein a drain terminal of the second transistor is connected to a source terminal of the seventh transistor and a source terminal of the eighth transistor,
wherein a drain terminal of the third transistor is connected to a source terminal of the ninth transistor and a source terminal of the tenth transistor, and
wherein a drain terminal of the fourth transistor is connected to a source terminal of the eleventh transistor and a source terminal of the twelfth transistor.

20. A phase shifter comprising:
an I/Q generator configured to generate an in-phase signal and a quadrature-phase signal based on an input signal;
a vector synthesis circuit configured to generate a first differential signal pair and a second differential signal pair, and generate an output signal based on the first differential signal pair and the second differential signal pair;
a first digital-to-analog converter (DAC) configured to transmit first and second current control signals to the vector synthesis circuit to control the in-phase signal; and
a second DAC configured to transmit third and fourth current control signals to the vector synthesis circuit to control the quadrature-phase signal,
wherein the vector synthesis circuit includes:
a first differential signal pair generator configured to generate the first differential signal pair based on the in-phase signal; and
a second differential signal pair generator configured to generate the second differential signal pair based on the quadrature-phase signal.
